(19) United States
(12) Patent Application Publication
(10) Pub. No.: US 2001/0044174 A1
(43) Pub. Date: Nov. 22, 2001

(54) Semiconductor device and method of fabricating the same

(75) Inventor: Nobuhisa Hamatake, Tokyo (JP)

Correspondence Address: SUGHRUE, MION, ZINN,, MACPEAK & SEAS, PLLC, 2100 Pennsylvania Avenue, NW, Washington, DC, 20037-3213, US

(73) Assignee: NEC CORPORATION

(21) Appl. No.: 09/904,513

(22) Filed: Jul. 16, 2001

Related U.S. Application Data
(62) Division of application No. 09/620,224, filed on Jul. 20, 2000.

(30) Foreign Application Priority Data
Jul. 21, 1999 (JP) 11-206528

(51) Int. Cl. H01L 21/00; H01L 21/84; H01L 21/20

(52) U.S. Cl. 438/149; 438/396

(57) ABSTRACT

A semiconductor device comprising full depletion type (FD) PMOS transistors of higher Vt. The transistors for a cell unit in this semiconductor device consist of PMOS transistors formed on a SOI substrate.

### BACKGROUND OF THE INVENTION

1. Field of the Invention

The present invention relates to a semiconductor device and a method of fabricating the same, more particularly to a full depletion type DRAM having a high threshold voltage Vt, and a method of fabricating the same.

2. Description of the Related Art

Semiconductor devices of SOI (Silicon on Insulator) type, having thin layers of silicon formed on insulation films are known, and those semiconductor devices comprised of thin-film SOI/CMOSs are particularly capturing much attention recently.

The reason for this is that the thin-film SOI/CMOS technology has become comparatively easy to get substrates for. As a consequence, the thin-film SOI/CMOS technology has made drastic advances and become capable of mass production.

By the way, SOI MOSFETs are capable of reductions in S/D (source/drain) junction capacitance between their sources and drains.

Besides, full depletion type (FD) MOSFETs can be device-designed to have an S value (subthreshold coefficient) as close to an ideal value (60 mV/dec) as possible. The FD MOSFETs are therefore superior to conventional bulk CMOSs in low voltage and high speed operation.

In particular, a reduction of diffusion layer leak current improves the hold time of DRAM cell transistors.

The full depletion type (FD) MOSFETs, however, cannot be device-designed to have higher threshold voltages Vt. That is, Vt typically has a value less than 0.3 V. This may cause semiconductor devices driven at lower voltages to make improper operations especially of write data.

The solutions thereto include the use of partial depletion type (PD) transistors. Nevertheless, in these partial depletion type (PD) transistors, the threshold voltage Vt in question varies due to floating body effects (or floating body condition), precluding the possibility of stable circuit operations.

In addition, a typical model of semiconductor device, or a DRAM, and especially the transistors for the logic units of the DRAM lose the above-described advantage of high speed operations. This leaves the problem that the SOI cell transistors make malfunctions more often. On this account, it has been desired that the cell transistors in the DRAM be realized as full depletion type (FD) transistors of higher Vt.

Moreover, conventional semiconductor devices in practical applications have exclusively used NMOS transistors. The actual use of PMOS transistors has been rare by reason of variations in substrate voltage and the need for an additional power supply circuit.

Meanwhile, Japanese Patent Laid-Open Publication No. Hei 8-37312 describes SOI type semiconductor devices. The essential technique disclosed therein is to make the gate insulation film of an NMOS transistor in a SOI type CMOS greater than the gate insulation film of a PMOS transistor in thickness so that the threshold value of the NMOS transistor is adjusted without affecting the threshold value of the PMOS transistor. The Publication, however, presents neither description nor suggestion as to a DRAM composed of PMOS transistors.

Additionally, Japanese Patent Laid-Open Publication No. Hei 2-209772 discloses a technique of reducing the thickness of the channel region in a MOS transistor formed on a SOI substrate or making the conduction type of the channel region identical to the conduction type of the source-drain so that the MOS transistor is improved in drain breakdown voltage and operating speed. Again, the Publication presents neither description nor suggestion as to a DRAM composed of PMOS transistors.

### SUMMARY OF THE INVENTION

An object of the present invention is to overcome the above-described drawbacks in the conventional art, and to provide a semiconductor device, or a DRAM in particular, comprising a full depletion type (FD) PMOS transistor of higher Vt, along with a method of fabricating the same.

A semiconductor device according to the present invention comprises a transistor for cell unit consisting of a PMOS transistor formed on a SOI substrate. More specifically, the semiconductor device according to the present invention is a DRAM, for example. Besides, the semiconductor device according to the present invention is a semiconductor device or a DRAM, wherein the gate electrode of the PMOS transistor is composed of an N-type gate electrode.

Moreover, a method of fabricating a semiconductor device according to the present invention is a method of fabricating the semiconductor device comprising a cell transistor consisting of a PMOS transistor formed on a SOI substrate. In the method of fabricating a semiconductor device, the semiconductor device is a DRAM, and the gate electrode of the PMOS transistor is composed of an N-type gate electrode.

Adopting the techniques and configurations as described above, the semiconductor device and the method of fabricating a semiconductor device according to the present invention can realize a full depletion type (FD) transistor of higher Vt. Therefore, in DRAM cell transistor applications, it is possible to secure sufficient operating margins for sense amplifiers. In addition, OFF currents can be reduced to make a significant improvement in DRAM hold time.

Moreover, the DRAM cell transistor uses a SOI-structured transistor to allow isolation of its diffusion layer from the substrate and the oxide film, thereby reducing the diffusion layer leak current greatly. This realizes a significant improvement in DRAM hold time.

Furthermore, the adoption of a SOI-structured PMOS transistor for the DRAM cell transistor suppresses substrate bias effects (floating body effects). At the same time, Vt is stabilized since the DRAM cell transistor is a fully-deleted (FD) transistor.

The nature, principle, and utility of the invention will become more apparent from the following detailed description when read in conjunction with the accompanying drawings in which like parts are designated by like reference numerals.

### BRIEF DESCRIPTION OF THE DRAWINGS

In the accompanying drawings:

FIG. 1 is a sectional view showing the configuration of the semiconductor device according to a first embodiment of the present invention; and

FIGS. 2A and 2B are sectional views showing the configuration of the semiconductor device according to a second embodiment of the present invention.

### DETAILED DESCRIPTION OF THE PREFERRED EMBODIMENT

Hereinafter, the semiconductor devices and the methods of fabricating a semiconductor device according to the embodiments of the present invention will be described in detail with reference to the accompanying drawings.

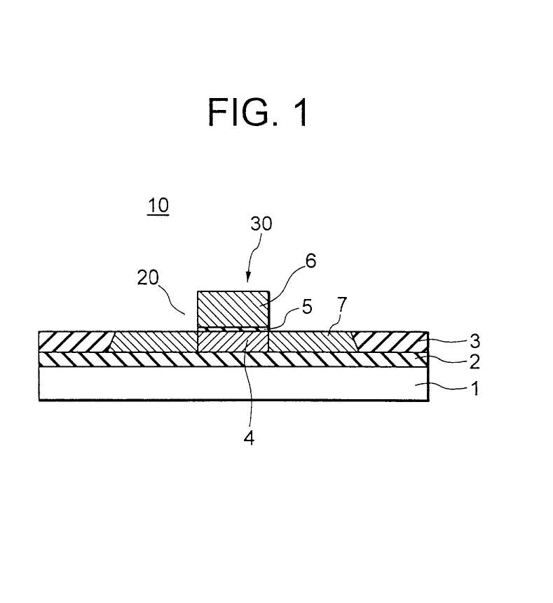

FIG. 1 is a diagram showing a semiconductor device 10 according to a first embodiment of the present invention. This semiconductor device 10 comprises cell transistors 20 consisting of PMOS transistors 30 formed on a SOI substrate 1. This semiconductor device 10 is particularly desirable to be a DRAM. FIG. 1 is a sectional view showing an example of the configuration of a PMOS transistor in a part of this DRAM (semiconductor device 10).

An embedded oxide film 2 having a thickness on the order of e.g. 100 nm is formed on the SOI substrate 1. A field oxide film 3 serving as an element isolation region defines an element forming region on this embedded oxide film 2. An N-type channel region 4 and a P-type diffusion layer 7 are formed at the center and in the periphery of the element forming region, respectively. On the N-type channel region 4 is formed a gate electrode 6 of N-type polysilicon through the intervention of a gate oxide film 5. The N-type channel region 4 has an impurity concentration on the order of 1.0×10¹⁷ cm⁻³, for example.

In the DRAM as a concrete example of the semiconductor device according to the present invention, the gate electrode 6 of the PMOS transistor 30 formed on the SOI substrate 1 is preferably an N-type layer, and such an N-type gate electrode 6 can be made of e.g. polysilicon. In other words, the gate electrode 6 is preferably formed of N-type polysilicon.

In the DRAM 10 of the present invention, all the cell transistors 20 preferably consist of PMOS transistors 30 formed on the SOI substrate 1. In particular, it is best preferable that all the PMOS transistors 30 formed on the SOI substrate 1 to constitute the cell transistors 20 in the DRAM described above have their gate electrodes 6 formed of N-type polysilicon.

In a further-detailed concrete example of the semiconductor device 10 according to the present invention, those PMOS transistors formed on the SOI substrate 1 to constitute the logic units of the DRAM are configured to be driven with a low threshold voltage Vt. Meanwhile, those PMOS transistors formed on the SOI substrate 1 to constitute the cell units of the DRAM are configured to be driven with a high threshold voltage Vt.

Accordingly, in the DRAM as a concrete example of the semiconductor device in the present invention, it is also preferable, for example, that those PMOS transistors formed on the SOI substrate 1 for the logic units have their gate electrodes composed of P-type gate electrodes while those PMOS transistors formed on the SOI substrate 1 for the cell units of the DRAM have their gate electrode composed of N-type gate electrodes.

The N-type polysilicon gate electrodes 6 can be formed, for example, by subjecting non-doped polysilicon formed by a CVD method to POCl₃ gas heated in an oxidizing atmosphere so that phosphorous is diffused into the non-doped silicon to form an N-type silicon.

The impurity concentration is determined by the diffusion temperature. In this example, approximately 900° C. heating makes a concentration of 1.0×10²¹ cm⁻³.

Moreover, in the present invention, the N-type channel regions 4 are designed to be 50 nm or so in thickness and 1.0×10¹⁷ cm⁻³ or so in impurity concentration so that the PMOS transistors 30 formed on the SOI substrate 1, of those cell transistors 20 constituting the cell units of the DRAM 10 are made into full depletion type (FD) transistors.

In the present embodiment, impurity concentrations greater than the value mentioned above would preclude the depletion layers in the PMOS transistors 30 formed on the SOI substrate 1 from reaching the embedded oxide film 2 in operation, thereby ending up with partial depletion type (PD) transistors.

Since the present invention adopts the configurations as described above, the PMOS transistors 30 formed on the SOI substrate 1 function as full depletion type (FD) transistors. As a result, the depletion layers in the PMOS transistors 30 reach the embedded oxide film in operation, whereby the gate oxide films, the depletion layers, and the embedded oxide film are connected in series as gate capacitance. The gate capacitance is significantly small as compared to those of bulk transistors and partial depletion type (PD) transistors.

This can reduce the sub-threshold coefficient (S), achieving low-Vt transistors of smaller OFF current.

The sub-threshold coefficient is given by Eq. 1 below.

$$\begin{matrix}S = ln 10 \times ( kT / q ) \times ( 1 + Cd / Cox ) \\ = 2.3 \times 0.0259 ( \text{room temperature} ) \times ( 1 + ϵ si \cdot tox / ϵ ox \cdot d\end{matrix} \qquad ( 1 )$$

In Eq. 1, k denotes a Boltzmann's constant, T denotes a temperature, q denotes an electric charge quantity, Cd denotes a capacitance value of layer consisted of SOI film+embedded oxide film, and Cox denotes a capacitance value of a gate oxide film. Also, ∈ si denotes a dielectric constant of Si, tox denotes a thickness of a gate oxide film, and ∈ ox denotes a dielectric constant of oxide film.

In full depletion type (FD) transistors, d (=SOI film thickness+embedded oxide film thickness)>>tox. This allows the approximation of the S value, or the subthreshold coefficient, to the ideal value (60 mV/dec.).

The full depletion type (FD) PMOS transistors, however, have a problem that their channel impurity concentrations cannot be made greater to set the threshold voltage Vt at significantly high values.

On the other hand, partial depletion type (PD) transistors have the advantage that the threshold voltage Vt control can be freely designed by means of channel concentrations. Nevertheless, due to the presence of non-depleted regions in part of the channels, hot carriers (holes) generated at the drain ends cause substrate currents, accumulating electric charges to the non-depleted regions in part of the channel regions. This gives rise to another problem that substrate bias effects (floating body effects) tend to vary the threshold voltage Vt and induce parasitic bipolar operations. In extreme cases, such phenomena can occur even in full depletion types.

Accordingly, the realization of full depletion type (FD) transistors having higher threshold voltages Vt is desired in this concrete example. In particular, the DRAM cell transistors require rather high Vt for the sake of holding data as well as securing operational margins for sense amplifiers.

Now, the threshold voltage Vt of a full depletion type (FD) transistor is given by Eq. 2 below.

Vt=Vfb+2øB−q·NA·Tsoi/Cox (2)

In Eq. 2, Vfb denotes a flat band voltage, øB denotes a work function, q denotes a quantity of electric charge, NA denotes a number of carrier, Tsoi denotes a thickness of a SOI film, and Cox denotes a capacitance value of a gate oxide film.

Accordingly, the use of PMOS transistors having their gate electrodes formed of N-type polysilicon for the DRAM cell transistors adds the work function to Vfb so that Vt can be designed higher by that value.

Moreover, holes, or the carriers in PMOSs, generate a smaller substrate current than electrons in NMOSs do. This suppresses the substrate bias effects (floating body effects).

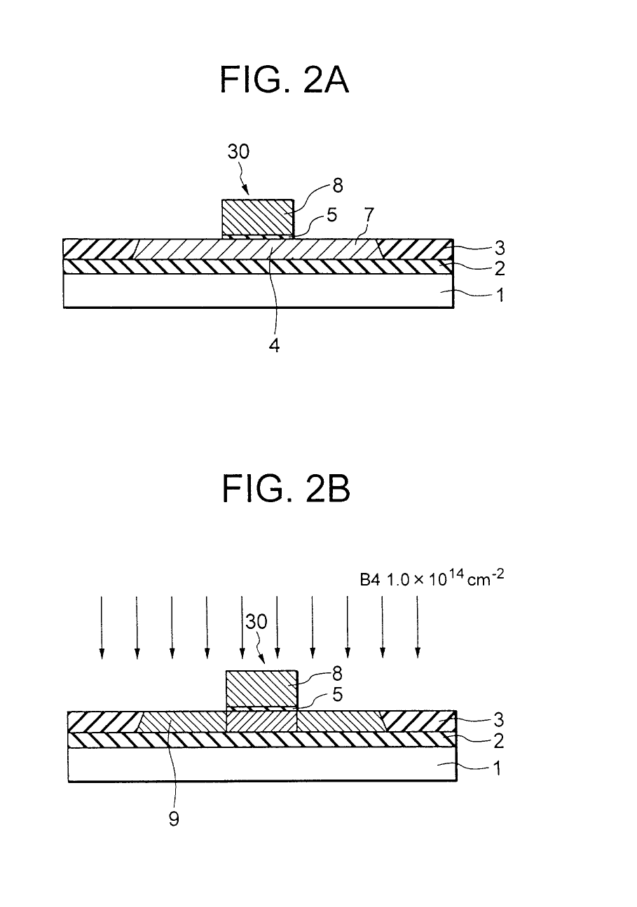

Now, the semiconductor device according to a second embodiment of the present invention will be described with reference to FIGS. 2A and 2B.

In the DRAM of the first embodiment described above, those PMOS transistors constituting cell transistors are configured to be driven with a high threshold voltage Vt. This causes a problem because those logic-unit PMOS transistors in this DRAM are also put under a high Vt while they prefer lower threshold voltages vt for high speed operations.

Therefore, in this second embodiment, the gate electrodes 8 of PMOS transistors are first formed on a SOI substrate 1 by using a doped polycrystalline Si method, as shown in FIG. 2A. Here, the gate electrodes 8 are formed of N-type polysilicon containing impurities on the order of e.g. 5.0×10¹⁹ cm⁻³ in impurity concentration.

For PMOS transistors 30 functioning as logic transistors formed on the SOI substrate 1 to be actuated with an ordinary low threshold voltage Vt, boron of the order of 5.0×10¹⁵ cm⁻² is implanted by ion implantation method, so as to form P-type diffusion layers and invert the gate electrodes from N-type to P-type.

This lowers the work function included in the Vfb of the above-mentioned general equation representing the threshold voltage Vt of a PMOS transistor 30. Since the threshold voltage Vt of the PMOS transistors declines by that difference, it becomes possible to realize the PMOS transistors 30 to be driven with a low threshold voltage Vt.

Meanwhile, as shown in FIG. 2B, PMOS cell transistors 20 on the SOI substrate 1 are formed by implanting boron of the order of 1.0×10¹⁴ cm⁻² by the ion implantation method when forming P-type diffusion layers.

In this case, the diffusion layers obtained are of P-type and low in impurity concentration while the gate electrodes are not inverted into P-type but left as N-type. This makes it possible to form those PMOS transistors 30 formed on the SOI substrate 1 to be driven with a higher threshold voltage Vt as in the concrete example described above.

As is evident from the descriptions above, the method of fabricating a semiconductor device in the present invention, and more specifically the method of fabricating a DRAM in the present invention, is a method of fabricating a semiconductor device, and more particularly a method of fabricating a DRAM, for constituting cell transistor units by only PMOS transistors formed on a SOI substrate.

Moreover, in the method of fabricating a semiconductor device according to the present invention, the gate electrodes of the PMOS transistors formed on the SOI substrate 1 preferably consist of N-type gate electrodes.

Furthermore, in the method of fabricating a semiconductor device according to the present invention, the gate electrodes of the PMOS transistors formed on the SOI substrate 1 also preferably made of polysilicon containing N-type impurities.

Meanwhile, in the method of fabricating a semiconductor device according to the present invention, those PMOS transistors formed on the SOI substrate 1 to constitute the logic units are preferably formed so that P-type diffusion layers are formed and the gate electrodes of the transistors are inverted from N-type to P-type. Those PMOS transistors formed on the SOI substrate 1 to constitute the cell units are preferably formed so that P-type diffusion layers are formed and the gate electrodes of the transistors are kept as N-type.

The semiconductor device according to the present invention can offer the following effects.

That is, as a first effect, higher threshold voltages Vt can be achieved of the PMOS transistors formed on a full depletion type (FD) SOI substrate 1. Therefore, in DRAM cell transistor applications, it is possible to secure sufficient operating margins for sense amplifiers.

In addition, OFF currents can be reduced to allow a significant improvement in DRAM hold time.

Moreover, as a second effect, the adoption of SOI-structured PMOS transistors for DRAM cell transistors allows isolation of the diffusion layers from the substrate and the oxide film, thereby reducing a diffusion layer leak current drastically. Therefore, the DRAM hold time can be improved significantly.

Furthermore, as a third effect, the adoption of SOI-structured PMOS transistors for DRAM cell transistors suppresses the substrate bias effects (floating body effects). The DRAM cell transistors, being full depletion type (FD) transistors, also offer the effect of Vt stabilization.

While there has been described what are at present considered to be preferred embodiments of the invention, it will be understood that various modifications may be made thereto, and it is intended that the appended claims cover all such modifications as fall within the true spirit and scope of the invention.

What is claimed is:

1. A semiconductor device comprising transistors for a cell unit consisted of PMOS transistors formed on an SOI substrate.

2. The semiconductor device according to claim 1, wherein said semiconductor device is a DRAM.

3. The semiconductor device according to claim 1 or 2, wherein the gate electrode of said PMOS transistor is composed of an N-type gate electrode.

4. The semiconductor device according to claim 3, wherein the gate electrode of said PMOS transistor is a gate electrode made of N-type polysilicon.

5. The semiconductor device according to claim 2, wherein said DRAM comprises a logic unit, and a PMOS transistor for said logic unit is driven with a low threshold voltage; and a PMOS transistor for said cell unit is driven with a high threshold voltage.

6. The semiconductor device according to claim 5, wherein: the gate electrode of the PMOS transistor for the logic unit is a P-type gate electrode; and the gate electrode of the PMOS transistor for the cell unit is an N-type gate electrode.

7. A method of fabricating a semiconductor device, forming transistors for a cell unit consisted of PMOS transistors formed on a SOI substrate.

8. The method of fabricating a semiconductor device according to claim 7, wherein said semiconductor device is a DRAM.

9. The method of fabricating a semiconductor device according to claim 7 or 8, wherein the gate electrode of said PMOS transistor is composed of an N-type gate electrode.

10. The method of fabricating a semiconductor device according to claim 9, wherein the gate electrode of said PMOS transistor is made of N-type polysilicon.

11. The method of fabricating a semiconductor device according to claim 8, wherein: said DRAM comprises a logic unit, and
when forming PMOS transistors for said logic unit, a P-type diffusion layer is formed and the gate electrode of this transistor is inverted from N-type to P-type; and,
when forming PMOS transistors for said cell unit, a P-type diffusion layer is formed and the gate electrode of this transistor is kept as N-type.
